(19) United States
(12) Patent Application Publication
(10) Pub. No.: US 2004/0011468 A1
(43) Pub. Date: Jan. 22, 2004

(54) Gas introduction system for temperature adjustment of object to be processed

(76) Inventors: Jun Hirose, Nirasaki-shi (JP); Shinji Hamamoto, Nirasaki-shi (JP); Hiroshi Koizumi, Nirasaki-shi (JP); Kenichi Nakagawa, Beverly, MA (US)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/443,001

(22) Filed: May 22, 2003

Related U.S. Application Data
(63) Continuation-in-part of application No. 10/283,041, filed on Oct. 30, 2002, now abandoned.
Application No. 10/283,041 is a continuation of application No. PCT/JP01/04447, filed on May 28, 2001.

(30) Foreign Application Priority Data
May 30, 2000 (JP) 2000-160453
May 29, 2001 (TW) 90112906

(51) Int. Cl. H01L 21/306

(52) U.S. Cl. 156/345.52; 156/345.53; 156/345.27

(57) ABSTRACT

According to the present invention, there is disclosed a gas introduction system for temperature adjustment comprising passing a gas whose temperature is managed for the temperature adjustment of an object to be processed between a mounting surface of a mounting base for holding the object to be processed under vacuum and a back surface of the object to be processed through a gas supply line, controlling a flow rate adjustment valve by control means based on a measured pressure of the gas supply line measured by a manometer, and adjusting a gas flow rate to the gas supply line so as to obtain a set pressure, so that the gas pressure can be set to a predetermined value in a short time, and the system is miniaturized with little waste of the gas.

### CROSS-REFERENCE TO RELATED APPLICATIONS

This is a Continuation-in-Part application of U.S. patent application Ser. No. 10/283,041, filed Oct. 30, 2002, which is a continuation application of PCT Application No. PCT/JP01/04447, filed May 28, 2001, which was not published under PCT Article 21(2) in English, and the entire contents of which are incorporated herein by reference.

This application is based upon and claims the benefit of priority from the prior Japanese Patent Application No. 2000-160453, filed May 30, 2000, the entire contents of which are incorporated herein by reference.

### BACKGROUND OF THE INVENTION

1. Field of the Invention

The present invention relates to a gas introduction system for temperature adjustment of an object to be processed, which introduces a gas for the temperature adjustment to a vacuum processing apparatus for subjecting an object to be processed such as a semiconductor substrate to a plasma processing, and more particularly, it relates to a gas introduction mechanism, an introduction method, and a leak detection method using this mechanism.

2. Description of the Related Art

For example, in a manufacturing process of a semiconductor device, vacuum processes performed in a vacuum atmosphere, such as a plasma etching process, ashing process, and sputter process have previously been in heavy usage with respect to a semiconductor wafer as an object to be processed.

For example, in the plasma etching process, a wafer support table for supporting the semiconductor wafer (hereinafter referred to as a wafer) is disposed in a vacuum chamber, and the wafer is electrostatically adsorbed and held by an electrostatic chuck disposed on the wafer support table.

Moreover, a shower head for introducing an etching gas into the vacuum chamber is disposed above the support table, and the etching gas is introduced into the chamber. Furthermore, a high frequency wave is supplied to at least one of the support table and shower head so that a high-frequency electric field is formed between the table and head, a plasma of processing gas is formed by this high-frequency electric field and the wafer is subjected to the plasma etching process.

During the process, when a wafer temperature rises due to the plasma, problems are generated such as breakdown of an element and nonuniformity of processing. Therefore, in order to prevent these problems occurring, the process is performed, while a cooling medium is passed through the support table and thereby the adsorbed wafer is cooled.

Additionally, in general, a microscopic space resulting from surface roughness exists between a mounting surface of a mounting base on which the wafer is mounted, such as the electrostatic chuck, and a wafer back surface. When a pressure inside the vacuum chamber is reduced in order to perform the plasma process in this state, the microscopic space is also brought into a vacuum state. Therefore, even when the support table is cooled as described above, and heat of the cooling is transmitted to the wafer via the electrostatic chuck, a heat transmission medium hardly exists in the microscopic space, so the wafer cannot be effectively cooled.

To solve the problem, gases having a relatively satisfactory heat conductivity, such as a helium (He) gas, have been introduced between the mounting base and the back surface of the wafer held on the mounting surface so as to efficiently cool the wafer. In this case, when a constant amount of He gas is sealed, or only a supply flow rate of the He gas is controlled, a leak of He gas introduced during the process is generated. Then, a heat transmission efficiency drops and the temperature of the wafer cannot be prevented from rising. Therefore, for example, in Jpn. Pat. Appln. KOKAI Publication No. 4-53135, there is proposed a technique of: disposing a mass flow controller in a gas line for supplying the He gas between the mounting base and the wafer held on the mounting surface; supplying the He gas at a constant flow rate; and measuring the pressure of the gas line and controlling an amount of He gas introduced between a support member and the wafer held on the mounting surface of the member by a flow rate control valve so that the pressure becomes constant.

However, the He gas is supplied at a constant flow rate in this control, and therefore much time passes until the gas pressure reaches a set value. Moreover, when the He gas is supplied at a constant flow rate in this manner, and after the gas pressure reaches the set value, a slight amount of gas is actually used from the supplied He gas to replenish the gas having leaked from the wafer. Most of the residual gas is exhausted without being effectively used, and the gas is wasted. Furthermore, the use of the mass flow controller requires a large-sized introduction system of the He gas, and causes a problem that installation requires a large space.

Additionally, there has been a demand for detection of a leak of the He gas from the wafer back surface, when the He gas is introduced in this manner. However, it is difficult to detect a leak of the He gas in the above-described introduction system of the He gas.

### BRIEF SUMMARY OF THE INVENTION

An object of the present invention is to provide a gas introduction system, mounted on a vacuum processing apparatus which subjects an object to be processed to a processing in a vacuum, for introducing a gas between a mounting surface of a mounting base to which the object to be processed is adsorbed and a back surface of the object to be processed, adjusting the temperature of the object to be processed by a mechanism in which a predetermined gas pressure is achieved with little waste in a short time and detecting a leak using the mechanism.

To achieve the above-described object, according to the present invention, there is provided a gas introduction system for temperature adjustment of an object to be processed, which introduces a gas for the temperature adjustment into a mounting base to hold the object to be processed under vacuum, and between a mounting surface of the mounting base and a back surface of the object to be processed held on the mounting base, the system comprising: a gas supply line which supplies the gas between the mounting base and the object to be processed held on the mounting base; a manometer which measures a pressure of the gas supply line; a flow rate adjustment valve which is mounted on an upstream side of the manometer and adjusts a gas flow rate of the gas supply line; and control means for controlling the flow rate adjustment valve so that the pressure measured by the manometer indicates a set pressure. A processing apparatus on which the gas introduction system for temperature adjustment according to the present invention is mounted is a vacuum processing apparatus which includes an exhaust system to evacuate the inside of a chamber, and subjects the object to be processed to a processing under vacuum.

Moreover, according to the present invention, there is provided a gas leak detection method using a gas introduction system for temperature adjustment of an object to be processed, which is mounted on a vacuum processing apparatus to subject the object to be processed to a processing under vacuum, and in which a gas for the temperature adjustment is supplied to a mounting base disposed in a chamber of the vacuum processing apparatus to hold the object to be processed, and between a mounting surface of the mounting base and a back surface of the object to be processed via a gas supply line, and a set pressure is obtained by a manometer and flow rate adjustment valve disposed halfway in the gas supply line, the gas leak detection method comprising:

closing the flow rate adjustment valve; bringing a space extending to the mounting surface of the mounting base from the flow rate adjustment valve of the gas supply line into a closed state; and detecting a gas leak between the mounting base and the object to be processed by the pressure of the gas supply line detected by the manometer in this state.

According to another aspect of the present invention, there is provided a gas leak detection method using a gas introduction system for temperature adjustment of an object to be processed, which is mounted on a vacuum processing apparatus to subject the object to be processed to a processing under vacuum, and in which a gas for the temperature adjustment is supplied to a mounting base disposed in a chamber of the vacuum processing apparatus to hold the object to be processed, and between a mounting surface of the mounting base and a back surface of the object to be processed via a gas supply line, and a set pressure is obtained by a manometer and flow rate adjustment valve disposed halfway in the gas supply line, the gas leak detection method comprising: closing the flow rate adjustment valve; bringing a space extending to the mounting surface of the mounting base from the flow rate adjustment valve of the gas supply line into a closed state; and detecting a gas leak between the mounting base and the object to be processed by the pressure of the gas supply line detected by the manometer in this state.

In the gas introduction system for temperature adjustment according to the present invention constituted as described above, the control means fully opens the flow rate adjustment valve until the pressure of the gas supply line reaches the set pressure, and the gas is rapidly supplied. After the pressure reaches the set pressure, the control means controls the flow rate adjustment valve to control a supply amount of gas. Thereby, a substantially necessary amount of gas is supplied, and an amount of wastefully exhausted gas is remarkably decreased. Since a mass flow controller requiring a regulator and including a large mechanism is not used in this constitution, the gas introduction system is simplified and miniaturized.

Moreover, the gas introduction system for temperature adjustment constituted as described above includes: the gas supply line which supplies the gas between the mounting base and the object to be processed held by the mounting base; the manometer which measures the pressure of the gas supply line; and the flow rate adjustment valve which is disposed on the upstream side of the manometer and adjusts the gas flow rate of the gas supply line. The flow rate adjustment valve is controlled so that the pressure measured by the manometer reaches the set pressure. In the constitution, the flow rate adjustment valve is closed, and the space extending to the mounting surface of the mounting base from the flow rate adjustment valve of the gas supply line is brought into the closed state. Then, if the leak is generated, the pressure of the gas supply line detected by the manometer drops. Therefore, when the pressure of the manometer is detected, the gas leak between the mounting base and the object to be processed can effectively be detected.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a sectional view showing a magnetron plasma etching apparatus on which a gas introduction system for temperature adjustment of an object to be processed according to one embodiment of the present invention is mounted.

FIG. 2 is an explanatory view of electric and magnetic fields formed in a chamber.

FIG. 3 is a diagram showing one constitution example of the gas introduction system for temperature adjustment of the object to be processed according to the present embodiment.

FIG. 4 is a diagram showing the constitution example of a pressure control valve for use in the gas introduction system for temperature adjustment of the object to be processed shown in FIG. 3.

FIG. 5 is a diagram showing the constitution example of a conventional gas introduction system for temperature adjustment of the object to be processed.

FIG. 6 is an explanatory view of a detection method of a leak from a wafer back surface.

FIG. 7 is a graph showing one example of a pressure change in a gas line by a leak state.

FIG. 8 is a diagram showing a modification example of a leak line in the gas introduction system for temperature adjustment of the object to be processed according to the present invention.

FIG. 9 is a diagram showing another constitution example of a pressure control valve for use in the gas introduction system for temperature adjustment of the object to be processed.

FIG. 10 is a diagram showing another example of the structure of the gas introduction mechanism of the present invention.

### DETAILED DESCRIPTION OF THE INVENTION

An embodiment according to the present invention will be described hereinafter in detail with reference to the drawings.

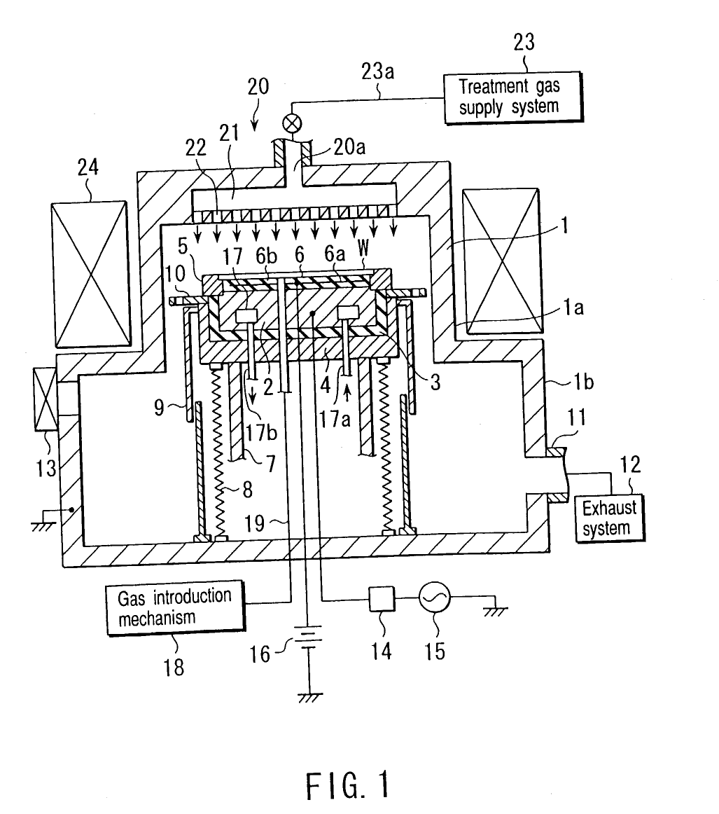

FIG. 1 is a diagram schematically showing a magnetron plasma etching apparatus on which a gas introduction system for temperature adjustment of an object to be processed according to the embodiment of the present invention is mounted.

This etching apparatus is constituted in an airtight manner, and includes a chamber 1 which has a stepped cylindrical shape including a small-diameter upper portion 1a and large-diameter lower portion 1b, and whose wall portion is formed, for example, of aluminum.

A support table 2 which horizontally supports a wafer W as an object to be processed is disposed in the chamber 1. The support table 2 is constituted, for example, of aluminum, and supported by a support base 4 as a conductor via an insulating plate 3. Moreover, a focus ring 5 formed of conductive materials such as monocrystal silicon is disposed on an outer periphery above the support table 2.

The support table 2 and support base 4 can be moved up and down by a ball screw mechanism including ball screws 7, and a driving portion below the support base 4 is covered with bellows 8 formed of stainless steel (SUS). The chamber 1 is grounded. Moreover, a bellows cover 9 is disposed outside the bellows 8. Additionally, a baffle plate 10 is disposed outside the focus ring 5, and this baffle plate 10 is electrically connected to the chamber 1 via the support base 4 and bellows 8.

An exhaust port 11 is formed in a side wall of the lower portion 1b of the chamber 1, and the exhaust port 11 is connected to an exhaust system 12. Moreover, when a vacuum pump of the exhaust system 12 is operated, a pressure in the chamber 1 can be reduced so as to obtain a predetermined degree of vacuum. On the other hand, a gate valve 13 which opens/closes a carrying inlet/outlet of the wafer W is disposed on an upper side of the side wall of the lower portion 1b of the chamber 1.

The support table 2 is connected to an RF power supply 15 via a matching box 14. The RF power supply 15 supplies a high-frequency power, for example, of 13.56 MHz to the support table 2. On the other hand, a shower head 20 described later is disposed opposite to, above and in parallel to the support table 2, and the shower head 20 is grounded. Therefore, the head and table function as a pair of electrodes.

An electrostatic chuck 6 for electrostatically adhering and holding the wafer W is disposed on the mounting surface of the support table 2, and the support table 2 and electrostatic chuck 6 constitute a mounting base of the wafer. This electrostatic chuck 6 is constituted by disposing an electrode 6a between insulating materials 6b, and the electrode 6a is connected to a direct-current power supply 16. Moreover, when a voltage is applied to the electrode 6a from the power supply 16, the semiconductor wafer W is adhered by a coulomb force.

A cooling medium chamber 17 is disposed inside the support table 2, and a cooling medium is introduced into the cooling medium chamber 17 via a cooling medium introduction tube 17a, discharged via a cooling medium discharge tube 17b and circulated. Heat of the cooling is transmitted to the wafer W via the support table 2, so that a processing surface of the wafer W is controlled at a desired temperature.

Moreover, even with the chamber 1 which is evacuated by the exhaust system 12 and held in a vacuum state, a gas for the cooling, such as an He gas, is introduced between the mounting surface of the electrostatic chuck 6 and the back surface of the wafer W by a gas introduction mechanism (the gas introduction system for temperature adjustment of the object to be processed) 18 via a gas supply line 19, so that the wafer W can be effectively cooled by the cooling medium circulated through the cooling medium chamber 17. When the cooling gas such as the He gas is introduced, the cooling heat of the cooling medium is effectively transmitted to the wafer W, and the cooling efficiency of the wafer W can be enhanced.

The shower head 20 is disposed opposite the support table 2 in a top wall portion of the chamber 1. The shower head 20 has a large number of gas delivery holes 22 in the lower surface thereof, and a gas introduction portion 20a is disposed above this holes. Moreover, a space 21 is formed inside this portion. The gas introduction portion 20a is connected to a gas supply pipe 23a, and the other end of the gas supply pipe 23a is connected to a processing gas supply system 23 which supplies a processing gas including a reactive gas for etching, and a dilution gas. Examples of the reactive gas include a halogen-based gas, examples of the dilution gas include Ar and He, and other gases for general use in this field can also be used. Such a processing gas is passed to the space 21 of the shower head 20 from the processing gas supply system 23 via the gas supply pipe 23a and gas introduction portion 20a, and delivered via the gas delivery holes 22.

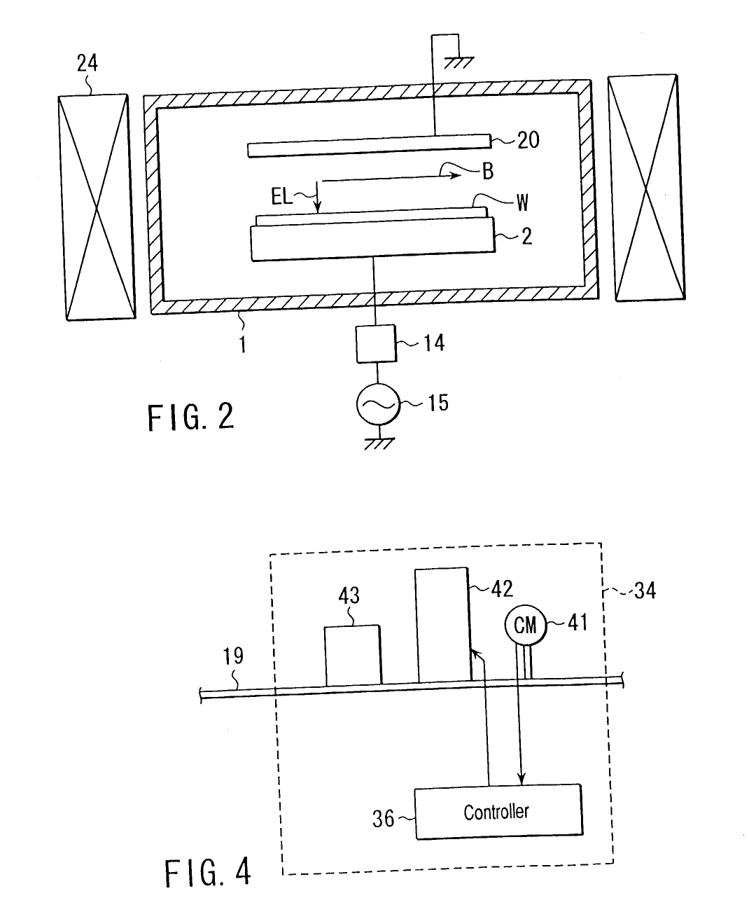

On the other hand, a dipole ring magnet 24 is concentrically disposed around the upper portion 1a of the chamber 1, and a horizontal magnetic field is formed in the space between the support table 2 and shower head 20. Therefore, in the space between the support table 2 and shower head 20, as shown as one example in FIG. 2, a vertical electric field EL is formed by the RF power supply 15, and a horizontal magnetic field B is formed by the dipole ring magnet 24. An orthogonal electromagnetic field formed in this manner generates a magnetron discharge, and this can form a plasma from the processing gas having a high energy state, and a predetermined film on the wafer W is etched by this plasma.

The gas introduction system for temperature adjustment of the object to be processed according to the present embodiment will next be described in detail.

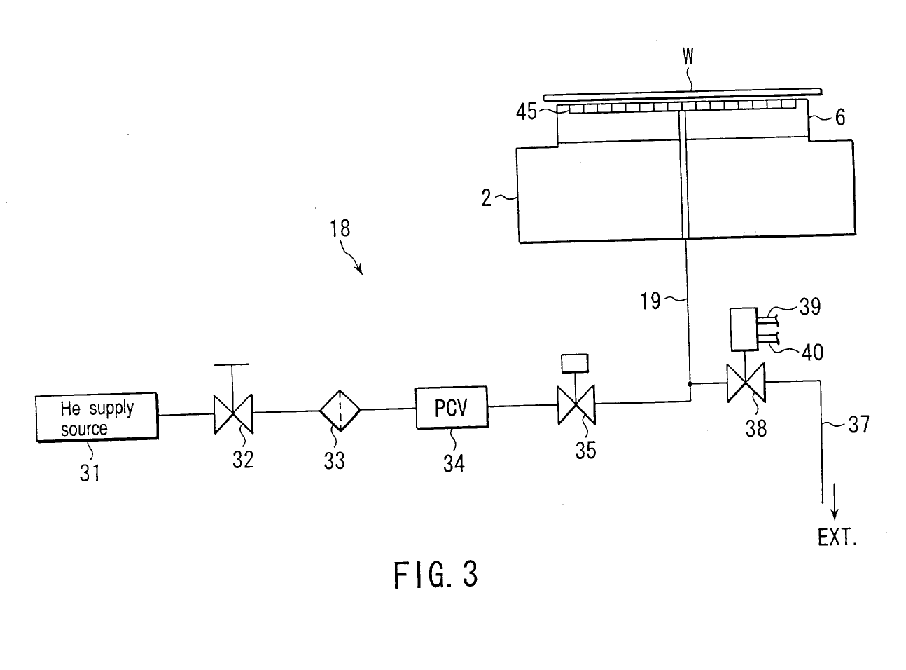

FIG. 3 is a diagram showing one constitution example of the gas introduction mechanism 18 in the present system. This gas introduction mechanism 18 uses main constituting elements including: the gas supply line 19 which supplies the He gas between the electrostatic chuck 6 functioning as the mounting base and the wafer W adhered/held by the electrostatic chuck 6 from an He supply source 31; a pressure control valve (PCV) 34 disposed in the gas supply line 19 to control a flow rate so that a gas pressure becomes constant; and a leak line 37 which allows the gas to leak from the gas supply line 19. Additionally, on the upstream side of the pressure control valve (PCV) 34 of the gas supply line 19, a valve 32 and filter 33 are arranged on the upstream side. A valve 35 is disposed on the downstream side of the pressure control valve (PCV) 34.

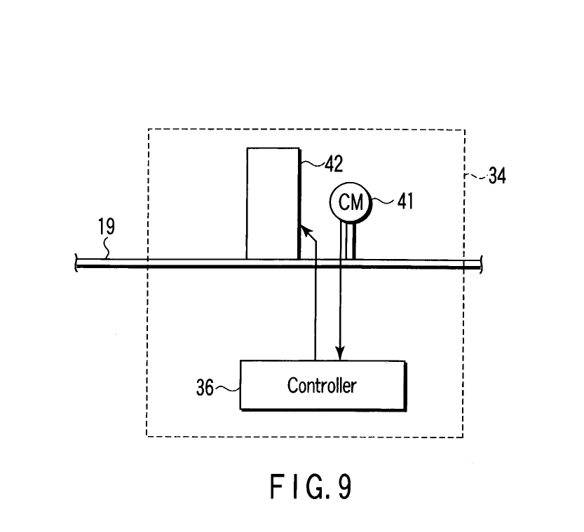

As shown in FIG. 9, the pressure control valve (PCV) 34 is manufactured by integrating a manometer for measuring the pressure of gas flowing through a gas supply line 19, for example a capacitance manometer (CM) 41, a flow rate adjustment valve, for example a piezo valve 42, and a controller 36 for controlling the piezo valve 42. The controller 36 controls the piezo valve 42 by a PID control, for example, based on the pressure of He gas measured by the capacitance manometer (CM) 41 to control the He gas flow rate so that the gas pressure becomes constant.

As shown in FIG. 4, the pressure control valve (PCV) 34 is manufactured by integrating a manometer for measuring the pressure of gas flowing through a gas supply line 19, for example a capacitance manometer (CM) 41, a flow rate adjustment valve, for example a piezo valve 42, a flowmeter 43, and a controller 36 for controlling the piezo valve 42. The controller 36 controls the piezo valve 42 by a PID control, for example, based on the pressure of He gas measured by the capacitance manometer (CM) 41 to control the He gas flow rate so that the gas pressure becomes constant. The flowmeter 43, which is located on the upstream side of the piezo valve 42, measures the rate of He gas flowing through the gas supply line 19 per unit of time. The output of the flowmeter 43 is input to a controller (not shown), and the controller outputs an interlock signal when the He gas flow rate per unit of time exceeds a threshold value, and interlocks, for example, the apparatus main body. In other words, the flowmeter 43 monitors changes in the rate of He gas flowing through the gas supply line 19. Based on the changes, i.e., based on the amount of He gas leakage, interlocking is performed. In this embodiment, it is possible to always monitor the amount of He gas leakage while He gas is flowing, in other words, without closing the gas line at a part on the downstream side of the piezo valve 42. Plasma discharges a great amount of heat, and for the processing, it is undesirable to stop the supply of He gas.

As shown in FIG. 3, a large number of gas delivery holes 45 are formed in the mounting surface of the electrostatic chuck 6, and the He gas passed through the gas supply line 19 at the predetermined pressure is introduced into a micro space between the mounting surface of the electrostatic chuck 6 and the wafer W adsorbed/mounted on the surface via the gas delivery holes 45. This gas pressure is set to a value at which a space having a uniform thickness is formed between the mounting surface of the electrostatic chuck 6 and the wafer W adsorbed/mounted on the surface.

Moreover, the leak line 37 is branched halfway from the gas supply line 19, and a two-stages flow rate variable valve 38 is disposed in the leak line 37. The leak line 37 has a function of finely adjusting the pressure, when the He gas is supplied to the back surface of the wafer W at the predetermined pressure via the gas supply line 19 during an etching process, and when the gas pressure excessively rises because of an error of the capacitance manometer (CM) 41, and the like. Furthermore, the leak line has a function of drawing the He gas from the back surface of the wafer W after the processing ends. However, when the leak line is used during the process, the flow rate may be small. During the evacuation, a large flow rate is required. Therefore, the two-stages flow rate variable valve 38 including an air introduction line 39 for the small flow rate and an air introduction line 40 for the large flow rate is used, and these lines are switched so as to pass a necessary flow rate of gas. When these two air introduction lines are closed, the leak line 37 is brought into a closed state.

A process operation in the magnetron plasma etching apparatus constituted as described above will next be described.

First, the operation comprises: bringing the gate valve 13 into an open state; carrying the wafer W into the chamber 1 by a carrying mechanism (not shown); mounting the wafer on the support table 2; subsequently retreating the carrying mechanism; and closing the gate valve 13. Additionally, the operation comprises: lifting up the support table 2 to a shown position; and evacuating the inside of the chamber 1 by a vacuum pump of the exhaust system 12 via the exhaust port 11.

Subsequently, after a predetermined degree of vacuum is obtained in the chamber 1, the operation comprises: introducing a predetermined processing gas into the chamber 1 from the processing gas supply system 23 at the predetermined flow rate; and supplying a high-frequency power, for example, having a frequency of 13.56 MHz and power of 1000 to 5000 W to the support table 2 from the RF power supply 15 in this state. The electric field is thereby formed between the shower head 20 as the upper electrode and the support table 2 as the lower electrode. In this case, the predetermined voltage is applied to the electrode 6a of the electrostatic chuck 6 from the direct-current power supply 16, and the wafer W is adsorbed/held, for example, by the coulomb force. On the other hand, the horizontal magnetic field is formed between the shower head 20 and support table 2 by the dipole ring magnet 24.

Therefore, the orthogonal electromagnetic field is formed in a processing space in which the wafer W exists, and the magnetron discharge is generated by a drift of electrons caused in this manner. Moreover, the plasma of the processing gas having the high energy state can be formed by the magnetron discharge, and the predetermined film formed on the wafer W is etched by the plasma.

In order to prevent the temperature of the wafer W from rising due to the plasma formed in this manner, the cooling medium is introduced into the cooling medium chamber 17 of the support table 2 during the etching process. Moreover, the He gas as the cooling medium is introduced between the mounting surface of the electrostatic chuck 6 and the back surface of the wafer W by the gas introduction mechanism 18 so that the cooling heat is effectively transmitted to the wafer W.

In this case, the mass flow controller is not provided in the gas supply line 19 of the gas introduction mechanism 18 in the present embodiment. Instead, a the manometer for measuring the pressure of the gas passing through the gas supply line 19 and a pressure control valve are provided in the gas supply line 19. The manometer is, for example, a capacitance manometer (CM) 41. The pressure control value is, for example, a pressure control valve (PCV) 34 that comprises a flow rate adjustment valve such as a piezoelectric valve 42, a flow meter 43, and a controller 36. The controller 36 controls the piezo valve 42, for example, by the PID control and controls the He gas flow rate based on the pressure of the He gas measured by the capacitance manometer (CM) 41 so that the gas pressure becomes constant. Therefore, different from the conventional mechanism in which the mass flow controller was used, the piezo valve 42 as the flow rate adjustment valve is fully opened and the gas can quickly be supplied by the controller 36 until the set pressure is reached. Additionally, after reaching the set pressure, the piezo valve 42 is controlled by the controller 36 and the supply amount of the He gas is controlled. Therefore, only the substantially necessary amount of He gas can be supplied, and the amount of exhausted gas can be greatly reduced. Moreover, the mass flow controller is large. Additionally, when the mass flow controller is used, the regulator is required. However, in the present embodiment, since such a mass flow controller is not used, and the regulator becomes unnecessary, the size of the gas introduction mechanism 18 can be smaller than that of the conventional gas introduction system. Furthermore, the pipe system is much simpler than the conventional system.

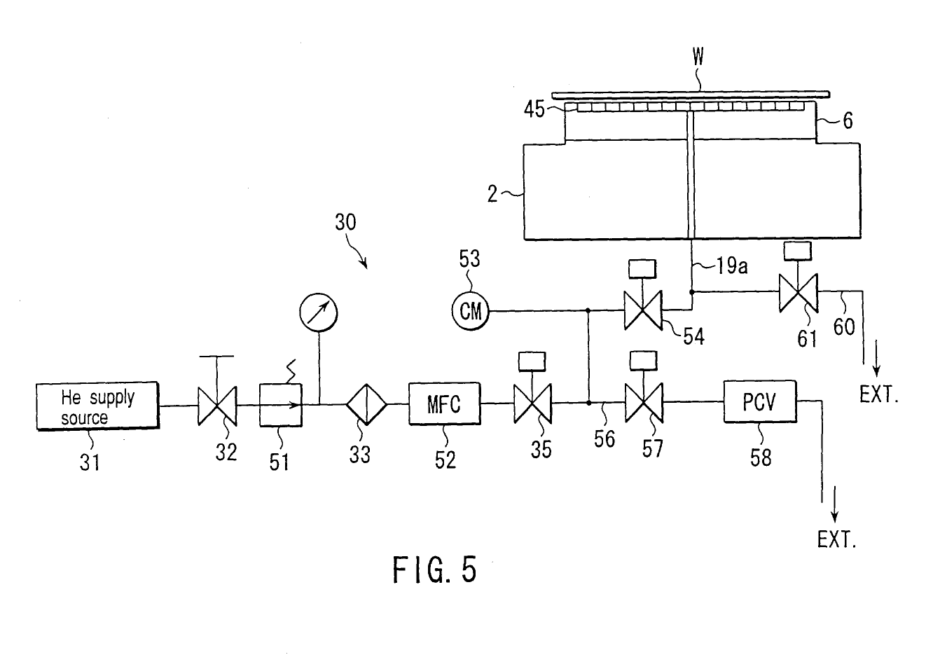

That is, as shown in FIG. 5, in a conventional gas introduction mechanism 30, a regulator 51 and mass flow controller (MFC) 52 are arranged in a gas supply line 19a, and the He gas is passed at a constant flow rate. The amount of He gas exhausted via an exhaust line 56 is controlled by a pressure control valve (PCV) 58 disposed in the exhaust line 56, so that the pressure value of a capacitance manometer 53 disposed in the gas supply line 19a is a set value.

In this constitution, previously, the gas of 2×10⁻² L/min was supplied. Assuming that a leak amount of the He gas from below the wafer W is 1×10⁻³ L/min, 1.9×10⁻² L/min is discarded. Moreover, it is necessary to dispose an evacuation line 60 for process end separately from the exhaust line 56. In this manner, for the conventional gas introduction mechanism 30, since the mass flow controller (MFC) 52 is disposed and the constant amount of He gas is introduced, much gas is wasted. Moreover, since the large-sized mass flow controller (MFC) 52 requiring the regulator 51 is disposed, the mechanism is large-sized and complicated. On the other hand, this problem can be solved in the gas introduction mechanism 18 of the above-described embodiment. Reference numerals 54, 57, 61 in FIG. 5 are valves disposed in each line.

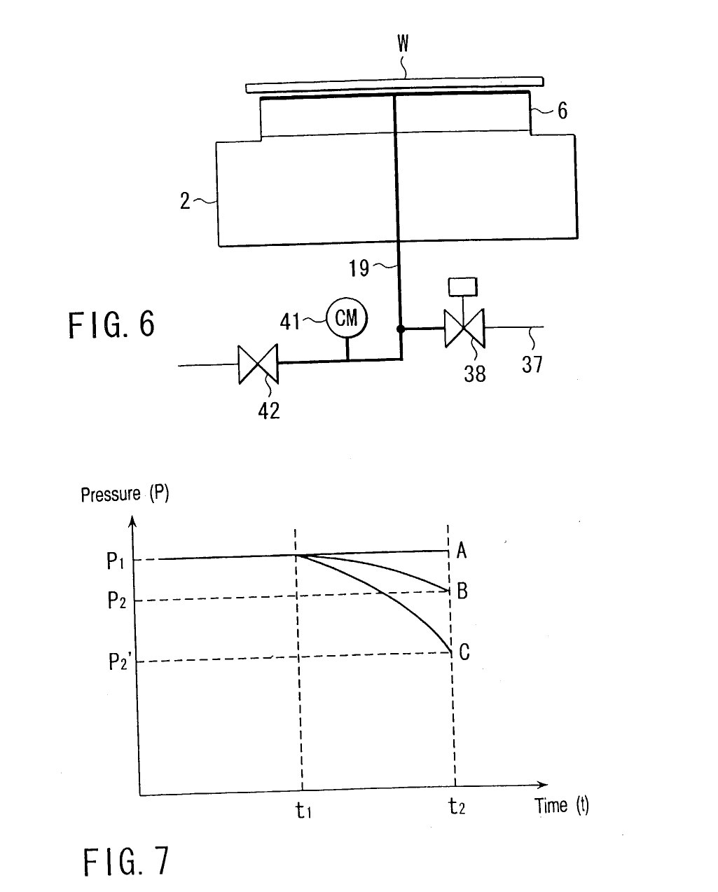

Moreover, when the gas introduction mechanism 18 is used, a leak from the back surface of the wafer W can be detected. In the constitution example shown in FIG. 6, when the gas supply line 19 is filled with He gas, and the piezo valve 42, and two-stage variable valve 38 are closed, the gas is sealed in a region shown by a bold black line in the drawing in the gas line. In this case, according to the state of the leak between the wafer W and the electrostatic chuck 6, the capacitance manometer (CM) 41 indicates the pressure as shown in one example of FIG. 7. That is, for A of FIG. 7, even with time elapse to t₂ from t₁, the pressure is unchanged at P₁, and a state in which there is not any leak is shown. Moreover, for B, with the time elapse to t₂ from t₁, the pressure drops to P₂ from P₁ to some degree, and a state in which there is a little leak is shown. For C, the pressure greatly drops with the lapse of time, indicating that there is big leak.

This pressure drop is used, the He gas leak amount between the electrostatic chuck 6 and wafer W is calculated, and this can be used as an interlock. That is, as shown in FIG. 7, when the pressure changes to P₂ from P₁ between t₁ and t₂, ΔP: P₂−P₁(Pa) and Δt=t₂−t₁(sec) are calculated. Assuming that the volume of a pipe portion shown by the black bold line in FIG. 6 is V(L), the volume of the gas having leaked between the wafer W and the electrostatic chuck 6 is

ΔV=V×ΔP/9.8×10⁴(L).

Therefore, a leak amount Q_{cal}(L/min) per minute is calculated by Q_{cal}=ΔV×60/Δt using the ΔV. Moreover, the interlock value of the leak amount is set to Q(L/min). When Q_{cal}>Q, the value is interlocked, and the gas leak can effectively be detected.

For example, two gas introduction systems are disposed to introduce the gas into the center portion of the wafer W and to introduce the gas into the edge portion of the wafer W, the gas for actual cooling is introduced by the middle gas introduction system, and the gas leak can be monitored by the gas introduction system of the edge portion.

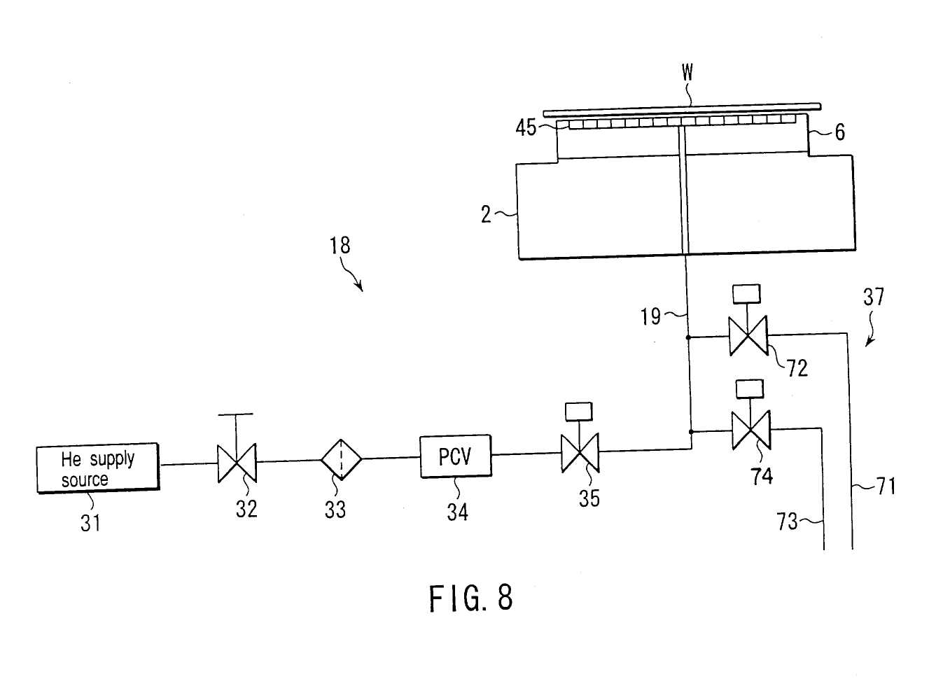

Additionally, the present invention is not limited to the embodiment, and can be variously modified. For example, in the above-described embodiment, the two-stage variable valve 38 is disposed in the leak line 37, but this is not limited. As shown in FIG. 8, there may be arranged a first line 71 using a valve 72 for allowing a small amount of gas to leak during the processing, and a second line 73 using a valve 74 having a large flow rate to draw air from the back surface of the wafer after the processing. Additionally, the constitution in which the two-stage variable valve is used becomes simpler because one line is sufficient.

Moreover, the pressure control valve constituted by integrating the capacitance manometer and piezo valve has been used in the above-described embodiment, but this is not limited, and the manometer may also be disposed separately from the valve. The manometer is not limited to the capacitance manometer and various manometers can be used. The flow rate adjustment valve is not limited to the piezo valve and, for example, a solenoid valve may also be used.

Furthermore, the use of the He gas as the gas has been described in the above-described embodiment, but this is not limited and other gases such as Ar or N₂ can be used. Additionally, He is more preferable, as it has a high heat conductivity.

Additionally, in the above-described embodiment, the case in which the present invention is applied to the magnetron plasma etching apparatus and the gas for cooling the wafer is supplied has been described. However, the present invention is not limited to this, and can be applied to all cases in which heat transmission is necessary between the object to be processed and the mounting base in a vacuum processing apparatus including a high number of heat transmission mediums. For example, the present invention can be processed even to a case in which the mounting base is heated in accordance with the process and this heat is transmitted to the object to be processed. Examples of this case include processes such as chemical vapor deposition (CVD).

Moreover, the case in which the electrostatic chuck 6 is disposed on the support table 2 as the mounting base and the object to be processed is held by the electrostatic chuck 6 has been described in the above-described embodiment, but the present invention is not limited to this, and the object may also be held using a mechanical clamp mechanism. Furthermore, the use of the semiconductor wafer as the object to be has processed been described, but the present invention is not limited to this, and other objects to be processed such as a liquid crystal display (LCD) substrate may also be used.

As described above, according to the present embodiment, there are disposed: a manometer which measures the pressure of the gas supply line; a flow rate adjustment valve disposed on the upstream side of the manometer to adjust the gas flow rate of the gas supply line; and a control means for controlling the flow rate adjustment valve so that the pressure measured by the manometer indicates the set pressure. Therefore, different from the conventional mechanism in which the mass flow controller was used, the control means can fully open the flow rate adjustment valve and rapidly supply the gas until the pressure reaches the set pressure. Additionally, after the pressure reaches the set pressure, the control means controls the flow rate adjustment valve and thereby controls the supply amount of gas. Therefore, the substantially necessary amount of gas can be supplied, and the amount of wastefully exhausted gas can be greatly reduced.

Moreover, different from the conventional mechanism, a mass flow controller requiring a regulator and having a large-sized mechanism is not used. Therefore, it is possible to miniaturize the entire gas introduction system. Furthermore, since the number of components decreases, costs can be lowered.

Additionally, according to the gas introduction system of the present embodiment, the flow rate adjustment valve is closed, and the space extending to the mounting surface of the mounting base from the flow rate adjustment valve of the gas supply line is brought into the closed state. Then, if a leak is generated, the pressure of the gas supply line detected by the manometer drops. Therefore, when the pressure of the manometer is detected, the gas leak between the mounting base and the object to be processed can be effectively detected.

As described above, in the gas introduction system for temperature adjustment of the present embodiment, there are disposed: a manometer which measures the pressure of the gas supply line; a flow rate adjustment valve disposed on the upstream side of the manometer to adjust the gas flow rate of the gas supply line; and a control means for controlling the flow rate adjustment valve so that the pressure measured by the manometer indicates the set pressure. Therefore, different from the conventional mechanism in which the mass flow controller was used, the control means can fully open the flow rate adjustment valve and rapidly supply the gas until the pressure reaches the set pressure. Additionally, after the pressure reaches the set pressure, the control means controls the flow rate adjustment valve and thereby controls the supply amount of gas. Therefore, the substantially necessary amount of gas can be supplied, and the amount of wastefully exhausted gas can be greatly reduced. Moreover, since the mass flow controller requiring a regulator and having a large-sized mechanism is not used, it is possible to miniaturize the gas introduction system, and the costs can be lowered.

Furthermore, the gas introduction system for temperature adjustment includes: the gas supply line which supplies the gas between the mounting base and the object to be processed held on the mounting base; the manometer which measures the pressure of the gas supply line; and the flow rate adjustment valve disposed on the upstream side of the manometer to adjust the gas flow rate of the gas supply line. The flow rate adjustment valve is controlled so that the pressure measured by the manometer indicates the set pressure. In this constitution, the flow rate adjustment valve is closed, and the space extending to the mounting surface of the mounting base from the flow rate adjustment valve of the gas supply line is brought into the closed state. Then, when the leak is generated, the pressure of the gas supply line detected by the manometer drops. Therefore, when the pressure of the manometer is detected, the gas leak between the mounting base and the object to be processed can effectively be detected.

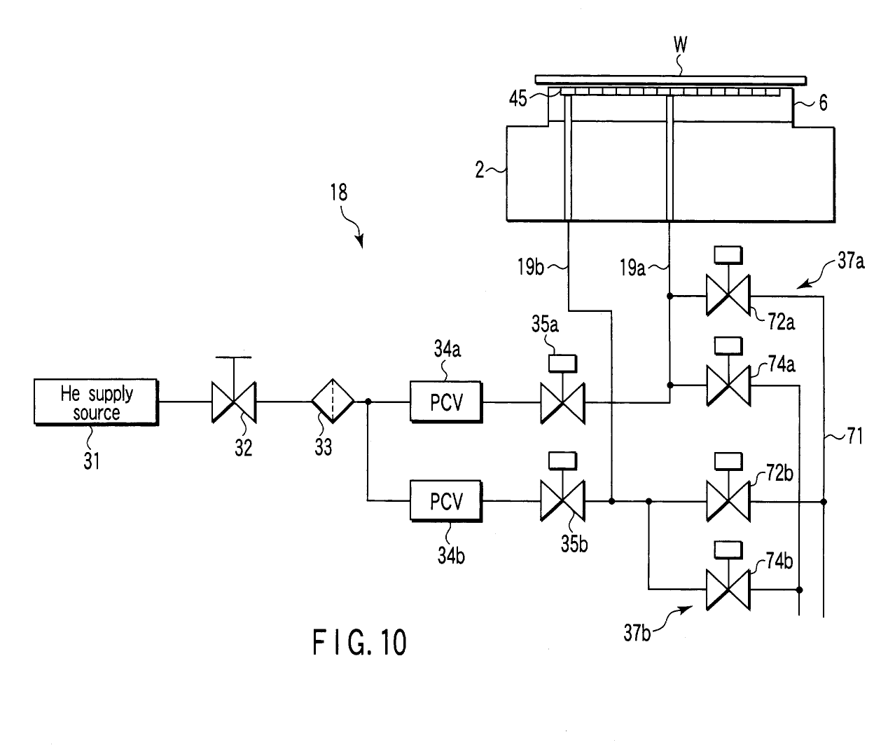

FIG. 10 illustrates another example of the structure of the gas introduction mechanism 18 of the present system. The difference from the gas introduction mechanism 18 shown in FIG. 8 lies in the gas supply line 19 for supplying He gas. The gas supply line 19 shown in FIG. 10 comprises a gas supply line 19a for supplying He gas to a center portion of an electrostatic chuck 6, and a gas supply line 19b for supplying He gas to an edge portion of the electrostatic chuck 6. The main components of the gas introduction mechanism 18 shown in FIG. 10 are a pressure adjustment valve 34 for controlling the flow rate so that the gas pressure becomes constant, and a leak line 37 for letting gas leak, as in the case of the third embodiment. As regards reference symbols, in FIG. 10, the letter “a” has been added for pressure adjustment valve 34, valve 35, leak line 37, valve 72 and valve 74 that are connected to gas supply line 19a, and the letter “b” has been added for pressure adjustment valve 34, valve 35, leak line 37, valve 72 and valve 74 that are connected to gas supply line 19b.

Since He gas, supplied between the mounting surface of the electrostatic chuck 6 and the wafer W, leaks from the edge portion of the electrostatic chuck 6, it is desirable to control the gas pressure so that the gas pressure of the gas supply line 19b is greater than that of the gas supply line 19a.

As can be seen from FIG. 6, He gas is supplied to the gas supply lines 19a and 19b,the valves 72a and 74a are opened, and the piezo valve 42 and valves 72b and 74b are closed to create a state in which the gas supply line 19b is filled with He gas for few seconds. While the gas supply line 19b is filled with He gas, the amount of He gas leakage from between the electrostatic chuck 6 and the wafer W is measured. The desirable timing of measurement is between the time at which the wafer W is adsorbed and thus held by the electrostatic chuck 6, and the time at which processing gas is introduced into the chamber to start the processing.

According to the present invention, there is provided a gas introduction system for temperature adjustment of an object to be processed, in which a gas pressure can be set to a predetermined value in a short time with little waste during the supplying of a gas between a mounting surface of a mounting base for holding the object to be processed under vacuum, and the back surface of the object to be processed, and which can be miniaturized. The gas introduction system for temperature adjustment is applied to a vacuum processing apparatus which subjects the object to be processed to a processing under vacuum, and comprises: passing the gas having the temperature controlled for the temperature adjustment of the object to be processed between the mounting surface of the mounting base for holding the object to be processed in the apparatus and the back surface of the object to be processed via a gas supply line; controlling a flow rate adjustment valve by control means based on a measured pressure of the gas supply line measured by a manometer; increasing a gas flow rate to the gas supply line until the set pressure is obtained; and adjusting the flow rate to obtain a necessary rate after the set pressure is achieved, so that the gas pressure can be set to the predetermined value in a short time, and the system can be miniaturized with little waste of the gas and with a simple constitution.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A gas introduction system for temperature adjustment of an object to be processed, which introduces a gas for the temperature adjustment into a mounting base to hold the object to be processed under vacuum, and between a mounting surface of the mounting base and a back surface of the object to be processed held on the mounting base, the system comprising:
a gas supply line which supplies the gas between the mounting base and the object to be processed held on the mounting base;
a manometer which measures a pressure of the gas supply line;
a flow rate adjustment valve which is disposed on an upstream side of the manometer and adjusts a gas flow rate of the gas supply line; and
control means for controlling the flow rate adjustment valve so that the pressure measured by the manometer indicates a set pressure,
wherein the gas supply line comprises a first gas line for supplying the gas to a center portion of the mounting base and a second gas line for supplying the gas to an edge portion of the mounting base, a pressure of the first gas line and a pressure of the second gas line are controlled so that the pressure of the second gas line is greater than the pressure of the first gas line, and the second gas line is brought into a closed state temporarily and a gas leak is measured based on an amount of change in the pressure of the second gas line while the second gas line is in the closed state.

2. The gas introduction system for temperature adjustment according to claim 1, further comprising a leak line which allows the gas to leak to the outside from the gas supply line.

3. The gas introduction system for temperature adjustment according to claim 2, wherein gas flow rate of the gas flowing through the leak line is changeable between at least two flow rates.

4. The gas introduction system for temperature adjustment according to claim 2, wherein the leak line comprises at least two lines that carry the gas flowing at different rates.

5. A gas introduction system for temperature adjustment of an object to be processed, which introduces a gas for the temperature adjustment into a mounting base to hold the object to be processed under vacuum, and between a mounting surface of the mounting base and a back surface of the object to be processed held on the mounting base, the system comprising:
a gas supply line which supplies the gas between the mounting base and the object to be processed held on the mounting base;
a flowmeter which measures a gas flow rate of the gas supply line;
a manometer which measures a pressure of the gas supply line;
a flow rate adjustment valve which is disposed on an upstream side of the manometer and adjusts the gas flow rate of the gas supply line; and
control means for controlling the flow rate adjustment valve so that the pressure measured by the manometer indicates a set pressure,
wherein a gas leak is measured based on an output of the flowmeter.

6. The gas introduction system for temperature adjustment according to claim 5, wherein the gas supply line comprises a first gas line for supplying the gas to a center portion of the mounting base and a second gas line for supplying the gas to an edge portion of the mounting base, and a pressure of the first gas line and a pressure of the second gas line are controlled so that the pressure of the second gas line is greater than the pressure of the first gas line.

7. The gas introduction system for temperature adjustment according to claim 5, further comprising a leak line which allows the gas to leak to the outside from the gas supply line.

8. The gas introduction system for temperature adjustment according to claim 7, wherein flow rate of the gas flowing through the leak line is changeable between at least two flow rates.

9. The gas introduction system for temperature adjustment according to claim 7, wherein the leak line comprises at least two lines that carry the gas flowing at different rates.

10. A plasma processing apparatus including a gas introduction system for temperature adjustment of an object to be processed, which introduces a gas for the temperature adjustment into a mounting base to hold the object to be processed under vacuum, and between a mounting surface of the mounting base and a back surface of the object to be processed held on the mounting base, the gas introduction system comprising:
a gas supply line which supplies the gas between the mounting base and the object to be processed held on the mounting base;
a manometer which measures a pressure of the gas supply line;
a flow rate adjustment valve which is disposed on an upstream side of the manometer and adjusts a gas flow rate of the gas supply line; and
control means for controlling the flow rate adjustment valve so that the pressure measured by the manometer indicates a set pressure,
wherein the gas supply line comprises a first gas line for supplying the gas to a center portion of the mounting base and a second gas line for supplying the gas to an edge portion of the mounting base, a pressure of the first gas line and a pressure of the second gas line are controlled so that the pressure of the second gas line is greater than the pressure of the first gas line, and the second gas line is brought into a closed state temporarily and a gas leak is measured based on an amount of change in the pressure of the second gas line while the second gas line is in the closed state.

11. The plasma processing apparatus according to claim 10, wherein the gas introduction system further comprises a leak line which allows the gas to leak to the outside from the gas supply line.

12. The plasma processing apparatus according to claim 11, wherein gas flow rate of the gas flowing through the leak line is changeable between at least two flow rates.

13. The plasma processing apparatus according to claim 11, wherein the leak line comprises at least two lines that carry the gas flowing at different rates.

14. A plasma processing apparatus including a gas introduction system for temperature adjustment of an object to be processed, which introduces a gas for the temperature adjustment into a mounting base to hold the object to be processed under vacuum, and between a mounting surface of the mounting base and a back surface of the object to be processed held on the mounting base, the gas introduction system comprising:
a gas supply line which supplies the gas between the mounting base and the object to be processed held on the mounting base;
a flowmeter which measures a gas flow rate of the gas supply line;
a manometer which measures a pressure of the gas supply line;
a flow rate adjustment valve which is disposed on an upstream side of the manometer and adjusts the gas flow rate of the gas supply line; and
control means for controlling the flow rate adjustment valve so that the pressure measured by the manometer indicates a set pressure,
wherein a gas leak is measured based on an output of the flowmeter.

15. The plasma processing apparatus according to claim 14, wherein the gas supply line comprises a first gas line for supplying the gas to a center portion of the mounting base and a second gas line for supplying the gas to an edge portion of the mounting base, and a pressure of the first gas line and a pressure of the second gas line are controlled so that the pressure of the second gas line is greater than the pressure of the first gas line.

16. The plasma processing apparatus according to claim 14, wherein the gas introduction system further comprises a leak line which allows the gas to leak to the outside from the gas supply line.

17. The plasma processing apparatus according to claim 16, wherein flow rate of the gas flowing through the leak line is changeable between at least two flow rates.

18. The plasma processing apparatus according to claim 16, wherein the leak line comprises at least two lines that carry the gas flowing at different rates.
